(19) United States
(12) Patent Application Publication
(10) Pub. No.: US 2026/0026077 A1
(43) Pub. Date: Jan. 22, 2026

(54) PAD STRUCTURE FOR SEMICONDUCTOR DEVICE

(71) Applicant: Micron Technology, Inc., Boise, ID (US)

(72) Inventors: Kevin L. BAKER, Boise, ID (US); Sheng Wei YANG, Boise, ID (US); Dong Wan KIM, San Jose, CA (US)

(21) Appl. No.: 19/216,884

(22) Filed: May 23, 2025

Related U.S. Application Data
(60) Provisional application No. 63/673,618, filed on Jul. 19, 2024.

(51) Int. Cl. H10D 64/66; H10B 53/30

(52) U.S. Cl. CPC H10D 64/661; H10B 53/30; H10D 64/668

(57) ABSTRACT

Implementations described herein relate to various structures, integrated assemblies, and memory devices. In some implementations, an integrated assembly includes a semiconductor device. The semiconductor device includes a columnar active area that includes a semiconductive material and a tip region having rounded convex corners that transition from a lateral surface of the columnar active area to vertical sidewalls of the columnar active area. The semiconductor device includes a pad structure directly conjoined with the tip region that includes a conductive material and an inner profile that conforms to the rounded convex corners, the lateral surface, and at least a portion of the vertical sidewalls.

### CROSS-REFERENCE TO RELATED APPLICATION

This Patent Application claims priority to U.S. Provisional Patent Application No. 63/673,618, filed on Jul. 19, 2024, entitled “PAD STRUCTURE FOR SEMICONDUCTOR DEVICE,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a pad structure for a semiconductor device.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell.

FIG. 2 is a diagrammatic view of an example semiconductor device structure described herein.

FIG. 3 is a flowchart of an example method of forming an integrated assembly or memory device having a pad structure described herein.

FIG. 4 is a flowchart of an example method of forming an integrated assembly or memory device having a pad structure described herein.

FIGS. 5A through 5G are diagrammatic views showing formation of the pad structure at example process stages of an example process of forming the pad structure.

FIG. 6 is a diagrammatic view of an example memory device described herein.

### DETAILED DESCRIPTION

Dynamic random access memory (DRAM) devices are fundamental components in modern electronics, providing fast and efficient data storage for a wide array of applications. As technology progresses, DRAM devices are pushed toward higher densities and performance, which drives continuous innovation in design and manufacturing of the DRAM devices. However, with the miniaturization of DRAM devices, challenges arise in forming a reliable contact structure in confined dimensions.

In some cases, an approach to fabricating the contact structure (e.g., a cell contact structure) may be restrictive in terms of electrically coupling the contact structure with a pad structure (e.g., a cell contact pad structure) that is reduced in size, increasing a need for precise targeting of the pad structure. The approach, which may include a subtractive etch operation, may lead to high contact resistance, or even fail to electrically connect the contact structure with the pad structure. Furthermore, additional layers (e.g., redistribution layers) that may be included as part of the pad structure may introduce complexity to the fabrication process that negatively impacts configuration of circuitry (e.g., bending of a word line structure) included in the DRAM device.

Some implementations described herein involve a method for manufacturing a semiconductor device including pad structures that connect with underlying active areas (access devices or source/drain regions, among other examples). The method may include receiving a semiconductor structure with an array of word lines and columnar active areas. The semiconductor structure includes a patterned dielectric layer that interleaves with a patterned hard mask structure that is directly on the word lines. The method may include removing portions of the dielectric layer to create approximately linear channels (e.g., cut rails) that a conductive layer subsequently fills. Portions of the conductive layer may then be subsequently removed to define pad structures having surface areas (e.g., landing areas or contact areas) that are expanded relative to surface areas of the columnar active areas.

The method may use the pattern of approximately linear channels to self-align the pad structures to the columnar active areas. By expanding the surface areas of the pad structures while maintaining precision in alignment, the method enables forming reliable electrical connections between contact structures and the pad structures that have low contact resistance to improve a performance, as well as a quality and reliability, of the semiconductor device. Furthermore, by accommodating constraints of device miniaturization, the method enables a reduction in sizes of the underlying active areas.

By improving the quality and/or the reliability of the semiconductor device, and enabling the reduction in sizes, an amount of resources used to support a market consuming the semiconductor device (e.g., raw materials, semiconductor manufacturing tools, labor, and/or computing resources) is reduced.

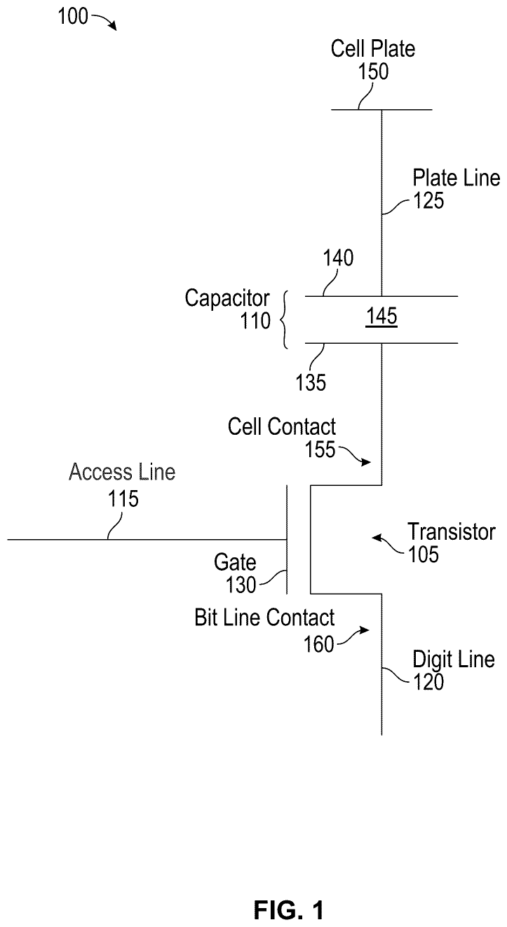

FIG. 1 is a circuit diagram of an example memory cell 100 described herein. In some implementations, the memory cell 100 is a ferroelectric memory cell. Alternatively, the memory cell 100 may be a linear dielectric memory cell or a paraelectric memory cell. As shown in FIG. 1, the memory cell 100 may include a transistor 105 (or another type of selection circuit) and a capacitor 110. The memory cell 100 may be accessed (e.g., written to, read from, and/or erased) using signals on a combination of lines that are coupled to the memory cell 100, shown as an access line 115 (sometimes called a “word line”), a digit line 120 (sometimes called a “bit line”), and a plate line 125.

The transistor 105 (sometimes called an access transistor) may include a gate 130. The capacitor 110 includes a bottom electrode 135 and a top electrode 140 separated by an insulator 145. In some implementations, the capacitor is a ferroelectric capacitor, and the insulator 145 is a ferroelectric insulator that comprises, consists of, or consists essentially of ferroelectric material. Alternatively, the capacitor may be a linear dielectric capacitor, and the insulator 145 may be a linear dielectric insulator that comprises, consists of, or consists essentially of linear dielectric material. Alternatively, the capacitor may be a paraelectric capacitor, and the insulator 145 may be a paraelectric insulator that comprises, consists of, or consists essentially of paraelectric material. When the access line 115 is activated (e.g., when a voltage is applied to the access line 115), the gate 130 coupled to the access line 115 may be activated. When the gate 130 is activated, the transistor 105 couples the digit line 120 to the bottom electrode 135 of the capacitor 110. A state of the memory cell 100 may then be written or read via the digit line 120.

The top electrode 140 of the capacitor 110 may be coupled to the plate line 125 and a cell plate 150. To write to (or program) the memory cell 100, the access line 115 may be activated, and a voltage may be applied across the capacitor 110 by controlling the voltage of the top electrode 140 (via the plate line 125 and/or the cell plate 150) and/or the bottom electrode 135 (via the digit line 120).

For a ferroelectric capacitor, the applied voltage creates an electric field, and the atoms in the ferroelectric material of the insulator 145 respond to the electric field to become arranged in a particular state (e.g., a particular orientation or polarization), which is representative of a data state (e.g., a logic “0” state or a logic “1” state). In some implementations, data may be stored using the capacitor 110 by controlling a voltage difference and/or a polarity difference of the capacitor 110 (e.g., of the insulator 145 between the bottom electrode 135 and the top electrode 140). For example, a voltage of the cell plate 150 and the digit line 120 may be controlled. In some implementations, a negative polarity of the insulator 145 as compared to the cell plate 150 results in a logic “0” state being stored in the capacitor 110, and a positive polarity of the insulator 145 as compared to the cell plate 150 results in a logic “1” state being stored in the capacitor 110. For a linear dielectric capacitor or a paraelectric capacitor, the cell plate 150 may grounded, and the capacitor 110 may be charged by applying a voltage to the bottom electrode 135 via the digit line 120.

To read the memory cell 100 (e.g., a state stored by the capacitor 110), the access line 115 may be activated, and a voltage may be applied to the plate line 125. Applying a voltage to the plate line 125 may cause a change in the stored charge on the capacitor 110. The magnitude of the change in stored charge may depend on the stored state of capacitor 110 (e.g., whether the stored state is a logic “1” state or a logic “0” state). This may or may not induce a threshold change in the voltage of the digit line 120 based on the charge stored on the capacitor 110. The change in voltage or lack of change in voltage of the digit line 120 (or a magnitude of the change in voltage) may be used to determine the stored state of the capacitor 110. For example, if the change in voltage satisfies a threshold, then the read operation indicates that a first state was stored in the capacitor 110, whereas if the change in voltage does not satisfy the threshold, then the read operation determines that a second state was stored in the capacitor 110. In some cases, multiple threshold voltages may be used, such as when the capacitor is capable of storing more than two data states (e.g., for a multi-level cell, a triple-level cell, and so on).

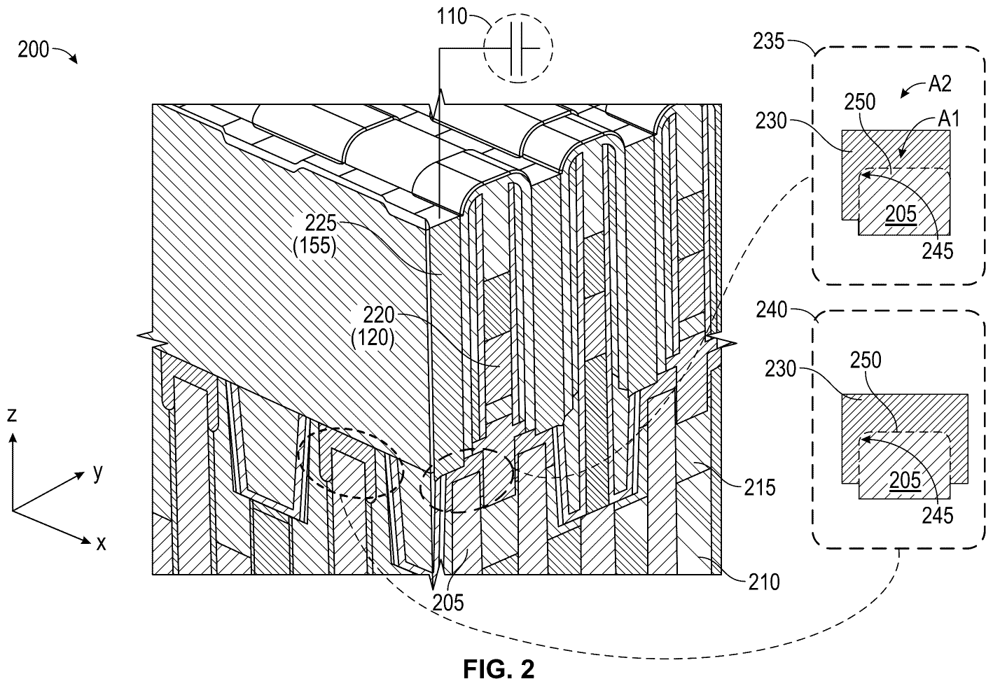

In some implementations, the memory cell 100 is accessed using a cell contact 155 and a bit contact 160. The cell contact 155 may be part of a connection between the capacitor 110 and the transistor 105, and the bit contact 160 may be part of a connection between the digit line 120 and the transistor 105. As described in greater detail in connection with FIGS. 2-6, the cell contact 155 may electrically connect with the transistor 105 using a pad structure (e.g., a cell contact pad structure) that includes an inner profile that conforms to rounded convex corners of an access device (e.g., an active area or a source/drain region of the transistor 105).

As indicated above, FIG. 1 is provided as an example. Other examples may differ from what is described with respect to FIG. 1.

FIG. 2 is a diagrammatic view of an example semiconductor device structure 200 described herein. In some implementations, the semiconductor device structure 200 includes one or more features of a memory cell (e.g., the memory cell 100 of FIG. 1).

As shown in the isometric view of FIG. 2, the semiconductor device structure 200 includes a semiconductive layer 205. The semiconductive layer 205 may be a semiconductor and may comprise, consist of, or consist essentially of semiconductive material. The semiconductive material may comprise, consist of, or consist essentially of silicon (e.g., polycrystalline silicon), among other examples. In some implementations, the semiconductive layer 205 comprises, consists of, or consists essentially of germanium, gallium arsenide, gallium nitride, silicon carbide, or another suitable semiconductive material, among other examples. In some implementations, a portion of the semiconductive layer 205 corresponds to a columnar active area (an access device or a source/drain region, among other examples).

The semiconductor device structure 200 may include a combination of dielectric layers, including dielectric layer 210 and dielectric layer 215. The dielectric layers 210 and 215 may each be an electrical insulator and may comprise, consist of, or consist essentially of insulative material. The insulative material may comprise, consist of, or consist essentially of silicon dioxide and/or silicon nitride, among other examples. In some implementations, a portion of the dielectric layer 210 may correspond to a shallow trench isolation (STI) region of the semiconductor device structure 200. Additionally, or alternatively, the dielectric layer 215 may provide additional insulative properties that enable electrical functionality of the semiconductor device structure 200.

The semiconductor device structure 200 may include a combination of conductive layers, including conductive layer 220 and the conductive layer 225, and conductive layer 230. The conductive layers 220 through 230 may each be an electrical conductor and may comprise, consist of, or consist essentially of conductive material. The conductive material may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped silicon, conductively-doped germanium, and/or conductively-doped gallium arsenide), among other examples. In some implementations, the conductive layer 220 corresponds to a bit line structure or a digit line structure of a memory cell (e.g., the digit line 120 described in connection with FIG. 1). Additionally, or alternatively and in some implementations, the conductive layer 225 corresponds to a contact structure of a memory cell (e.g., the cell contact 155 described in connection with FIG. 1). Additionally, or alternatively and in some implementations, the conductive layer 230 corresponds to a pad structure (e.g., a cell contact pad structure).

In some implementations, the semiconductive layer 205 (e.g., a source/drain region) electrically couples to the conductive layer 225 (e.g., the cell contact 155) through the conductive layer 230. Additionally, or alternatively and in some implementations, the conductive layer 230 electrically couples the semiconductive layer 205 with a capacitor (e.g., the capacitor 110) through the conductive layer 225.

As shown in the detailed section view 235, the conductive layer 230 is directly conjoined with a tip region of the semiconductive layer 205. The conductive layer 230 (e.g., a pad structure) has a first cross-sectional shape along a first plane (e.g., a y-z plane). The first cross-sectional shape may be a first polygon including two segments that are approximately orthogonal to one another, where one of the segments extends below a lateral surface (e.g., an upper horizontal surface) of the semiconductive layer 205. In other words, the first cross-sectional shape may be an “L” shaped cross-section that overhangs semiconductive layer 205.

As further shown in detailed section view 235, a surface of the semiconductive layer 205 (e.g., a lateral surface of the active area) has a first lateral surface area A1. Furthermore, a surface of the conductive layer 230 (e.g., a lateral surface of the pad structure) has a second lateral surface area A2, where the second lateral surface area A2 is greater than the first lateral surface area A1.

As shown in the detailed section view 240, the conductive layer 230 has a second cross-sectional shape along a second plane (e.g., an x-z plane). The second cross-sectional shape may be a second polygon including three segments, where two of the segments are approximately parallel to one another and extend below the lateral surface of the semiconductive layer 205. In other words, the second cross-sectional shape may be a “C” shaped cross-section that overhangs semiconductive layer 205.

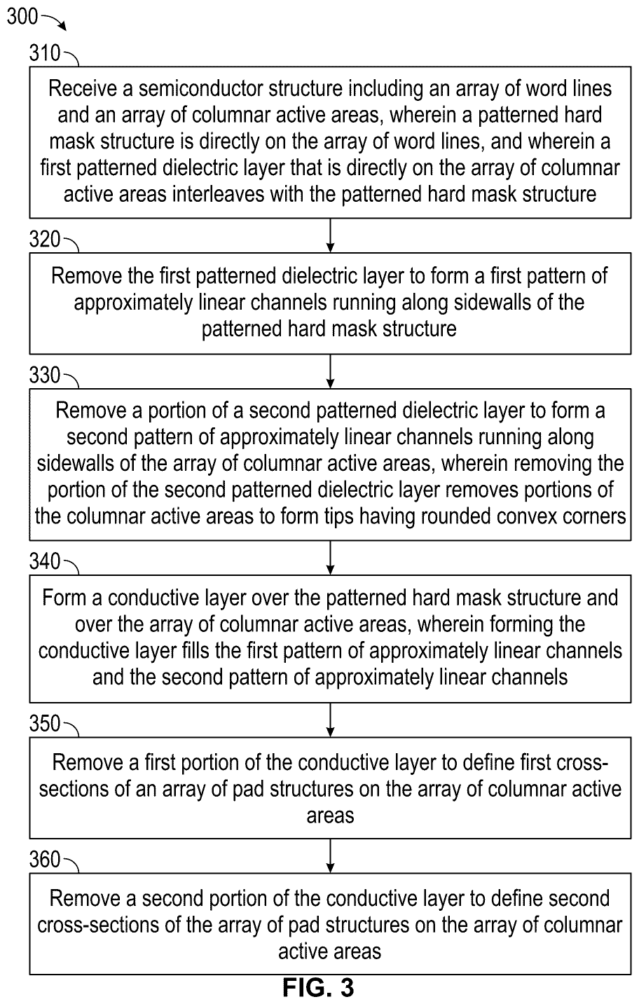

As shown in the detailed section views 235 and 240, the semiconductive layer 205 (e.g., a columnar active area) includes rounded convex corners 245 that transition the lateral surface of the semiconductive layer 205 to vertical sidewalls of the semiconductive layer 205. As described in greater detail in connection with FIGS. 3-5G, the rounded convex corners 245 (e.g., outwardly filleted edges) may be indicative of a subtractive etch process that is used as part of forming the semiconductor device structure 200.

The semiconductive layer 205 may include a profile 250 (e.g., an inner profile) that conforms to the rounded convex corners 245, the lateral surface, and at least a portion of the vertical sidewalls. In a case where the semiconductive layer 205 and the conductive layer 230 include a same base material (e.g., the semiconductive layer 205 may include polysilicon and the conductive layer 230 may include doped polysilicon), a grain boundary between the semiconductive layer 205 and the conductive layer 230 (e.g., along the profile 250) may include a junction between crystal structures of the semiconductive layer 205 and the conductive layer 230. In a case where the semiconductive layer 205 and the conductive layer 230 include different materials, the grain boundary between the semiconductive layer 205 and the conductive layer 230 (e.g., along the profile 250) may include discontinuities between crystal structures of the semiconductive layer 205 and the conductive layer 230.

As indicated above, FIG. 2 is provided as an example. Other examples may differ from what is described with regard to FIG. 2.

As described in connection with FIGS. 1 and 2, and in some implementations, an integrated assembly includes a semiconductor device (e.g., the semiconductor device structure 200). The semiconductor device includes a columnar active area (e.g., the semiconductive layer 205) that includes a semiconductive material and a tip region with an outer profile having rounded convex corners (e.g., the rounded convex corners 245) that transition from a lateral surface of the columnar active area to vertical sidewalls of the columnar active area. The semiconductor device includes a pad structure (e.g., the conductive layer 230) directly conjoined with the tip region. The pad structure has a conductive material and includes an inner profile (e.g., the inner profile 250) that conforms to the rounded convex corners, the lateral surface, and at least a portion of the vertical sidewalls.

Additionally, or alternatively and in some implementations, an apparatus (e.g., the semiconductor device structure 200) includes a source/drain region (e.g., the semiconductive layer 205). The source/drain region includes polysilicon and an end region. The end region includes a first lateral surface area (e.g., the lateral surface area A1) and outwardly filleted edges (e.g., the rounded convex corners 245). The apparatus includes a cell contact pad structure (e.g., the conductive layer 230). The cell contact pad structure includes a doped semiconductive material and a second lateral surface area (e.g., the lateral surface area A2), where the second lateral surface area is greater than the first lateral surface area. The apparatus includes a grain boundary that electrically couples the cell contact pad structure with the source/drain region. The grain boundary includes a profile (e.g., the profile 250) that conforms to the end region having the outwardly filleted edges. The apparatus includes a cell contact structure (e.g., the conductive layer 225) that electrically couples a capacitor to the source/drain region through the cell contact pad structure and the grain boundary.

In these ways, the implementations enable a reduction in sizes of the semiconductor device and/or the apparatus. Furthermore, the implementations establish reliable electrical connections that have low contact resistance to improve a performance, as well as a quality and reliability, of the semiconductor device and/or the apparatus. By improving the quality and/or the reliability of the semiconductor device and/or the apparatus, and enabling the reduction in sizes, an amount of resources used to support a market consuming the semiconductor device and/or the apparatus (e.g., raw materials, semiconductor manufacturing tools, labor, and/or computing resources) is reduced.

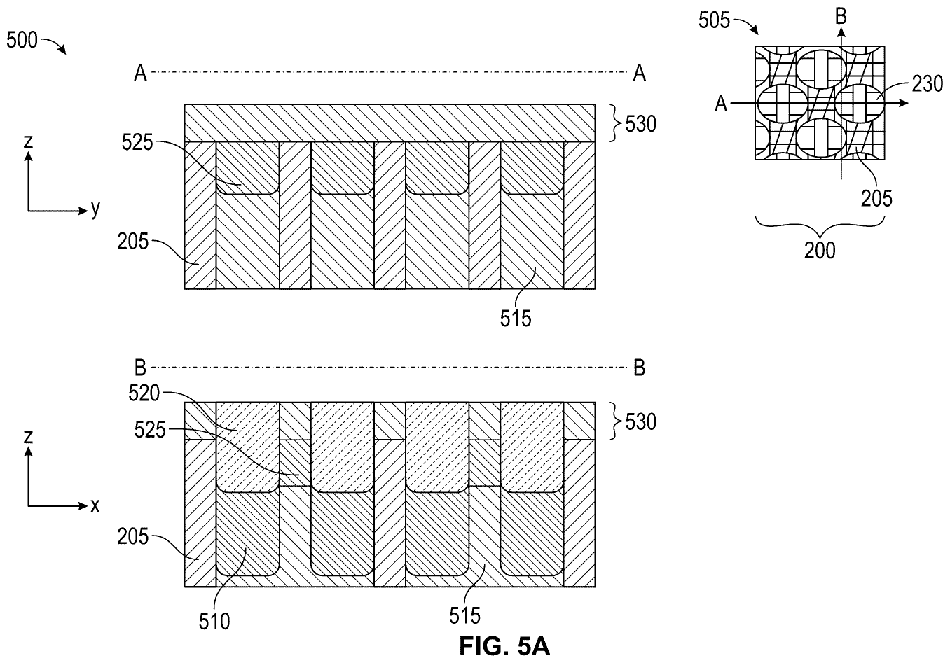

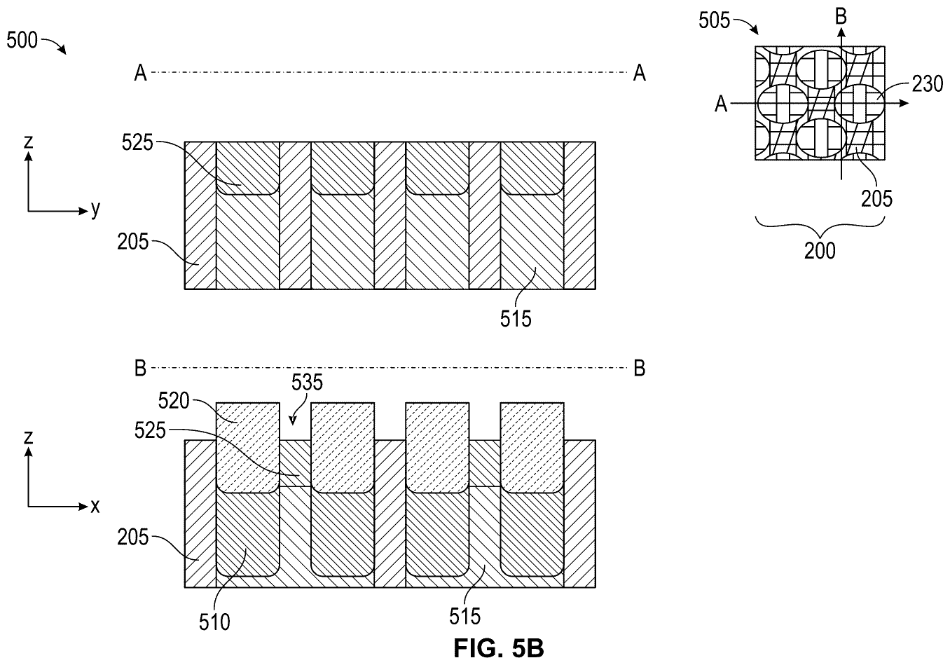

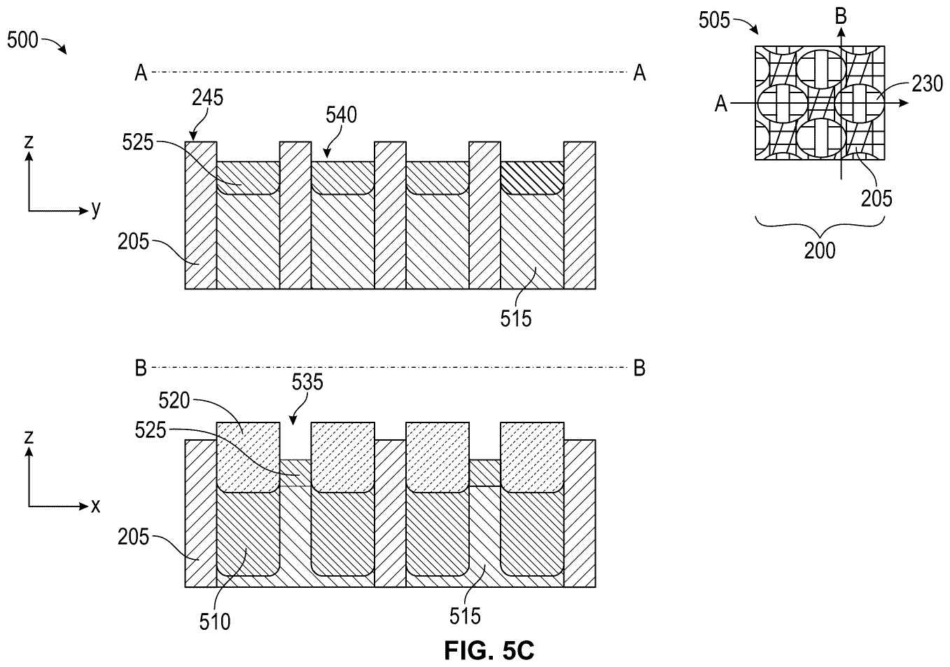

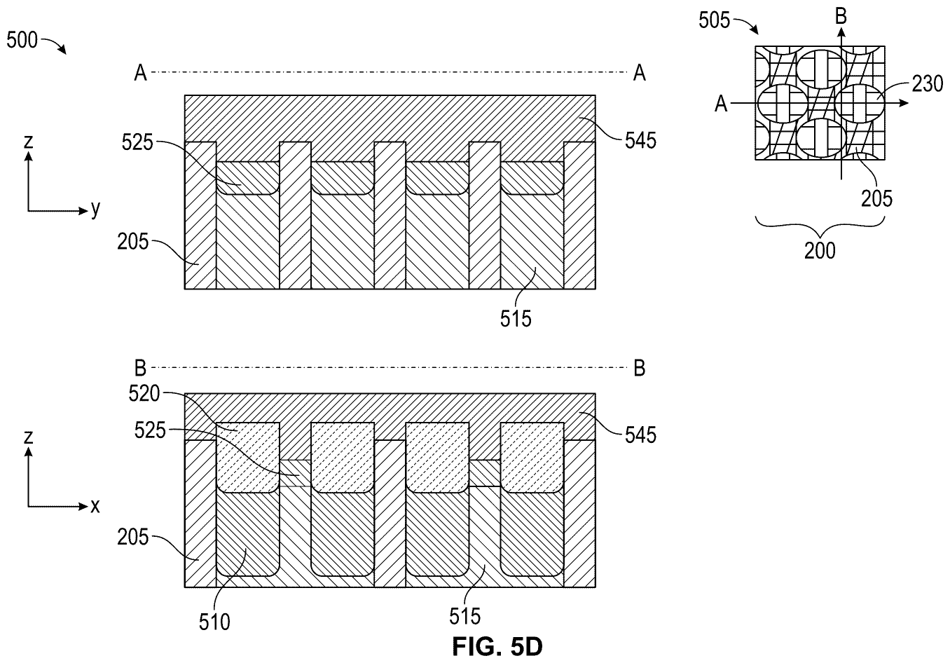

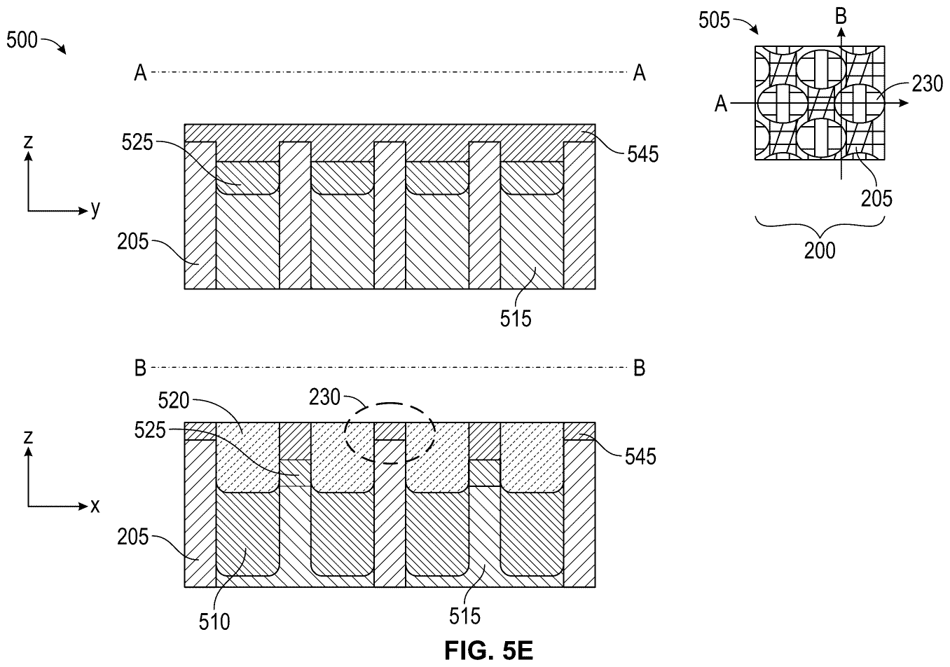

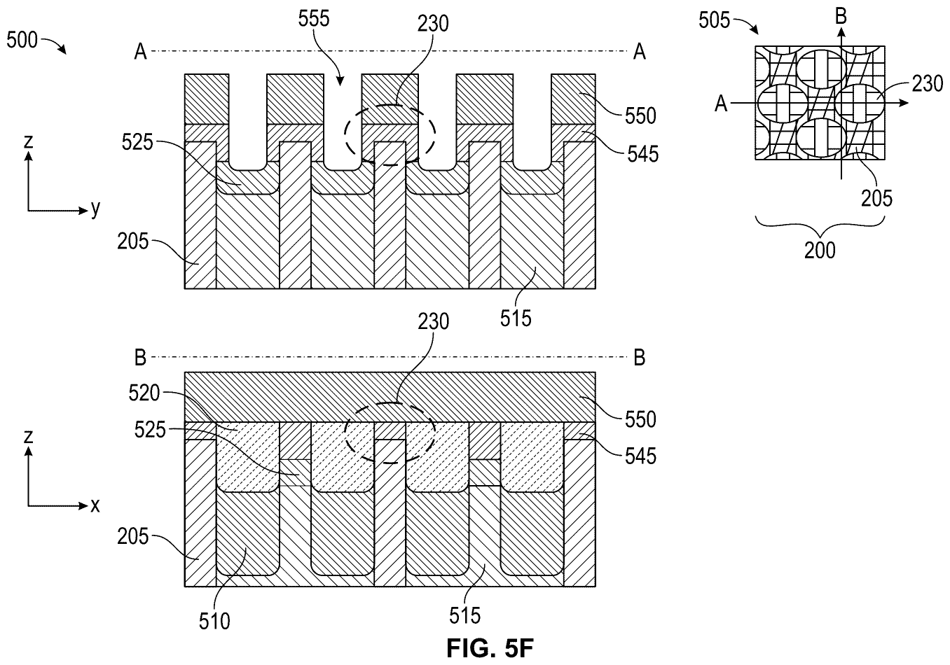

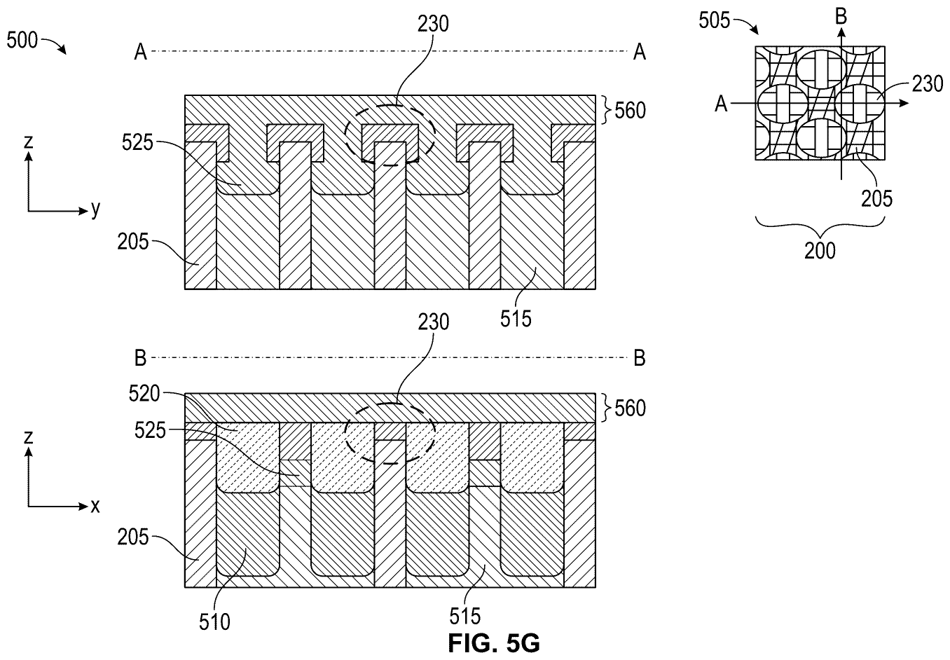

FIG. 3 is a flowchart of an example method 300 of forming an integrated assembly or memory device having a pad structure described herein (e.g., the conductive layer 230). In some implementations, and as described in greater detail in connection with FIGS. 5A-5G, one or more process blocks of FIG. 3 may be performed by various semiconductor manufacturing equipment.

As shown in FIG. 3, the method 300 may include receiving a semiconductor structure including an array of word lines and an array of columnar active areas, wherein a patterned hard mask structure is directly on the array of word lines, and wherein a first patterned dielectric layer that is directly on the array of columnar active areas interleaves with the patterned hard mask structure (block 310). As further shown in FIG. 3, the method 300 may include removing the first patterned dielectric layer to form a first pattern of approximately linear channels running along sidewalls of the patterned hard mask structure (block 320). As further shown in FIG. 3, the method 300 may include removing a portion of a second patterned dielectric layer to form a second pattern of approximately linear channels running along sidewalls of the array of columnar active areas, wherein removing the portion of the second patterned dielectric layer removes portions of the columnar active areas to form tips having rounded convex corners (block 330). As further shown in FIG. 3, the method 300 may include forming a conductive layer over the patterned hard mask structure and over the array of columnar active areas, wherein forming the conductive layer fills the first pattern of approximately linear channels and the second pattern of approximately linear channels (block 340). As further shown in FIG. 3, the method 300 may include removing a first portion of the conductive layer to define first cross-sections of an array of pad structures on the array of columnar active areas (block 350). As further shown in FIG. 3, the method 300 may include removing a second portion of the conductive layer to define second cross-sections of the array of pad structures on the array of columnar active areas (block 360).

The method 300 may include additional aspects, such as any single aspect or any combination of aspects described below and/or in connection with one or more other methods described elsewhere herein.

In a first aspect, forming the conductive layer includes forming the conductive layer using an epitaxial growth operation to grow a semiconductive layer and doping the semiconductive layer.

In a second aspect, alone or in combination with the first aspect, forming the conductive layer includes forming a metallic layer.

In a third aspect, alone or in combination with one or more of the first and second aspects, forming the conductive layer includes forming the conductive layer using a deposition operation to deposit the conductive layer, and planarizing the conductive layer after the deposition operation.

In a fourth aspect, alone or in combination with one or more of the first through third aspects, forming the array of columnar active areas includes forming the array of columnar active areas from polysilicon, and forming the conductive layer includes forming the conductive layer by depositing a metal on the polysilicon, and annealing the metal and the polysilicon to form a silicide.

In a fifth aspect, alone or in combination with one or more of the first through fourth aspects, removing the first portion of the conductive layer electrically isolates the array of pad structures across segments of the patterned hard mask structure.

In a sixth aspect, alone or in combination with one or more of the first through fifth aspects, removing the second portion of the conductive layer electrically isolates the array of pad structures across the array of columnar active areas.

In a seventh aspect, alone or in combination with one or more of the first through sixth aspects, removing the first portion of the conductive layer and removing the second portion of the conductive layer uses the patterned hard mask structure to self-align the array of pad structures to the array of columnar active areas.

In an eighth aspect, alone or in combination with one or more of the first through seventh aspects, removing the first portion includes removing the first portion using an etch back operation.

In a ninth aspect, alone or in combination with one or more of the first through eighth aspects, removing the second portion includes patterning a layer of photoresist over the conductive layer, and removing the second portion using a subtractive etch operation.

In a tenth aspect, alone or in combination with one or more of the first through ninth aspects, the method 300 includes forming a dielectric layer over the array of pad structures that conforms to surfaces of the array of pad structures, conjoins with the rounded convex corners, and extends below top surfaces of the patterned hard mask structure.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the pad structure (e.g., the conductive layer 230), an integrated assembly that includes the pad structure, any part described herein of the pad structure, and/or any part described herein of an integrated assembly that includes the structure pad structure. For example, the method 300 may include forming one or more of the parts of the memory cell 100 and/or the semiconductor device structure 200.

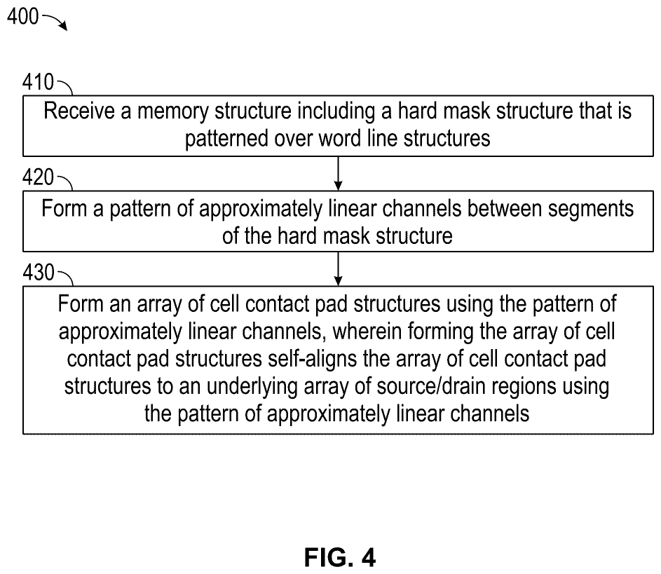

FIG. 4 is a flowchart of an example method 400 of forming an integrated assembly or memory device having a pad structure described herein (e.g., the conductive layer 230). In some implementations, and as described in greater detail in connection with FIGS. 5A-5G, one or more process blocks of FIG. 4 may be performed by various semiconductor manufacturing equipment.

As shown in FIG. 4, the method 400 may include receiving a memory structure including a hard mask structure that is patterned over word line structures (block 410). As further shown in FIG. 4, the method 400 may include forming a pattern of approximately linear channels between segments of the hard mask structure (block 420). As further shown in FIG. 4, the method 400 may include forming an array of cell contact pad structures using the pattern of approximately linear channels, wherein forming the array of cell contact pad structures self-aligns the array of cell contact pad structures to an underlying array of source/drain regions using the pattern of approximately linear channels (block 430).

The method 400 may include additional aspects, such as any single aspect or any combination of aspects described below and/or in connection with one or more other methods described elsewhere herein.

Although FIG. 4 shows example blocks of the method 400, in some implementations, the method 400 may include additional blocks, fewer blocks, different blocks, or differently arranged blocks than those depicted in FIG. 4. In some implementations, the method 400 may include forming the pad structure (e.g., the conductive layer 230), an integrated assembly that includes the pad structure, any part described herein of the pad structure, and/or any part described herein of an integrated assembly that includes the structure pad structure. For example, the method 400 may include forming one or more of the parts of the memory cell 100 and/or the semiconductor device structure 200.

FIGS. 5A through 5G are diagrammatic views showing formation of the pad structure (e.g., the conductive layer 230) at example process stages of an example process of forming the pad structure. In some implementations, the example process described below in connection with FIGS. 5A through 5G may correspond to the method 300, one or more blocks of method 300, method 400, and/or one or more blocks of the method 400. However, the process described below is an example, and other example processes may be used to form the pad structure, an integrated assembly that includes the pad structure, and/or one or more parts of the pad structure and/or the integrated assembly.

Cross-sectional views A-A and B-B of FIGS. 5A through 5G are derived with respect to top view 505 of the semiconductor device structure 200. As shown in top view 505, and in some implementations, a tip region of the semiconductive layer 205 (e.g., a tip region of the active areas or access device) has an approximately trapezoidal top view profile.

As shown in FIG. 5A, the process 500 may include receiving a structure (e.g., the semiconductor device structure 200) including the semiconductive layer 205 and a conductive layer 510. The conductive layer 510 that may comprise, consist of, or consist essentially of conductive material. The conductive material may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped silicon, conductively-doped germanium, and/or conductively-doped gallium arsenide), among other examples. The semiconductive layer 205 may correspond to an array of columnar active areas, and the conductive layer 510 may correspond to an array of word lines (e.g., an array of access lines 115 as described in connection with FIG. 1). As shown in FIG. 5B, the structure may include a dielectric region 515 (e.g., the dielectric layer 210 and/or the dielectric layer 215 of FIG. 1) that isolates and/or insulates the semiconductive layer 205 from the conductive layer 510.

As further shown in FIG. 5A, a dielectric layer 520 is over and/or on the conductive layer 510. The dielectric layer 520, which may correspond to a patterned hard mask structure, may be an electrical insulator and may comprise, consist of, or consist essentially of insulative material. The insulative material may comprise, consist of, or consist essentially of silicon dioxide and/or silicon nitride, among other examples.

The structure further includes a dielectric layer 525 and a dielectric layer 530. As shown in section B-B, the dielectric layer 525, which may be a patterned dielectric layer, may interleave with a lower portion of the dielectric layer 520. Additionally, or alternatively and as shown in section B-B, the dielectric layer 530, which may be a patterned dielectric layer, may interleave with an upper portion of the dielectric layer 520. The dielectric layer 525 and/or the dielectric layer 530 may each be an electrical insulator and may comprise, consist of, or consist essentially of insulative material. The insulative material may comprise, consist of, or consist essentially of silicon dioxide and/or silicon nitride, among other examples.

As shown in FIG. 5B, the process 500 may include removing (e.g., etching) the dielectric layer 530 to form a pattern of approximately linear channels 535 along sidewalls of the dielectric layer 520 (e.g., a pattern of rails running along sidewalls of the patterned hard mask structure). The removal may remove all material in the dielectric layer 530 down to the dielectric layer 525. Furthermore, the pattern of approximately linear channels 535 may include a linearity and/or a straightness within reasonable manufacturing capabilities and or tolerances of semiconductor manufacturing equipment, including lithography tools and/or etching tools used to form the pattern of approximately linear channels 535.

As shown in FIG. 5C, the process 500 may include removing (e.g., etching) a portion of the dielectric layer 525 to form a pattern of approximately linear channels 540 along sidewalls of the semiconductive layer 205 (e.g., a pattern of rails running along sidewalls of the array columnar active areas). The removal may include removing portions of the semiconductive layer 205 to form tips having the rounded convex corners 245. Furthermore, the pattern of approximately linear channels 540 may include a linearity and/or a straightness within reasonable manufacturing capabilities and or tolerances of semiconductor manufacturing equipment, including lithography tools and/or etching tools used to form the pattern of approximately linear channels 540.

As shown in FIG. 5D, the process 500 may forming (e.g., depositing or growing) a conductive layer 545 over (and/or on) the semiconductive layer 205 and over (and/or on) dielectric layer 520. Forming the conductive layer 545 may include filling the pattern of approximately linear channels 535 and/or filling the pattern of approximately linear channels 540. The conductive layer 545 may comprise, consist of, or consist essentially of a metal (e.g., titanium, tungsten, cobalt, nickel, platinum, and/or ruthenium), a metal composition (e.g., a metal silicide, a metal carbine, and/or a metal nitride, such as titanium nitride or titanium silicon nitride), and/or a conductively-doped semiconductive material (e.g., conductively-doped polysilicon, conductively-doped germanium, and/or conductively-doped gallium arsenide), among other examples.

As shown in FIG. 5E, the process 500 may include removing (e.g., etching back) a portion of the conductive layer 545 to define cross sections of an array of pad structures along a first direction (e.g., cross sections of the conductive layer 545 as shown in section B-B). In some implementations, and as shown in FIG. 5E, removing the portion includes etching the conductive layer 545 below a top surface of the dielectric layer 520 (e.g., below a top surface of the patterned hard mask structure).

As shown in FIG. 5F, the process 500 may include removing (e.g., subtractively etching) a portion of the conductive layer 545 to define cross sections of the array of pad structures along a second direction (e.g., cross sections of the conductive layer 545 as shown in section A-A). In some implementations, and as shown in FIG. 5F, a mask 550 (e.g., a photoresist mask) may be used to define the cross sections. For example, the mask 550 may be deposited and/or patterned on the conductive layer 545 to form cavities 555 prior to removing the portions to define the cross sections.

As shown in FIG. 5G, the process 500 may include forming (e.g., depositing, growing) a dielectric layer 560 over and/or on the conductive layer 230 (e.g., over and/or on the pad structures). The dielectric layer 560 may be an electrical insulator and may comprise, consist of, or consist essentially of insulative material. The insulative material may comprise, consist of, or consist essentially of silicon dioxide and/or silicon nitride, among other examples.

As indicated above, the process steps described in connection with FIGS. 5A through 5G are provided as examples. Other examples may differ from what is described with respect to FIGS. 5A through 5G. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, chemical mechanical planarization, or another removal technique.

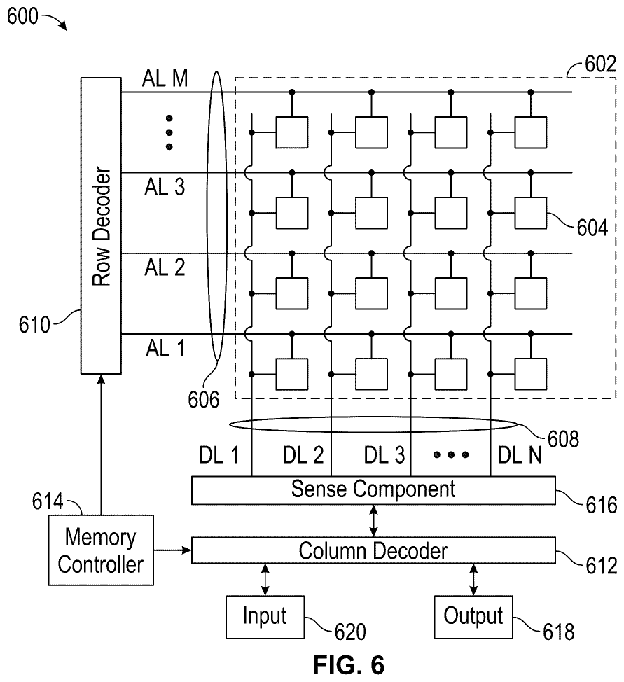

FIG. 6 is a diagrammatic view of an example memory device 600 described herein. The memory device 600 may include a memory array 602 that includes multiple memory cells 604. A memory cell 604 is programmable or configurable into a data state of multiple data states (e.g., two or more data states). For example, a memory cell 604 may be set to a particular data state at a particular time, and the memory cell 604 may be set to another data state at another time. A data state may correspond to a value stored by the memory cell 604. The value may be a binary value, such as a binary 0 or a binary 1, or may be a fractional value, such as 0.5, 1.5, or the like. A memory cell 604 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 604 by activating or selecting the appropriate access line 606 (shown as access lines AL 1 through AL M) and digit line 608 (shown as digit lines DL 1 through DL N). An access line 606 may also be referred to as a “row line” or a “word line,” and a digit line 608 may also be referred to a “column line” or a “bit line.” Activating or selecting an access line 606 or a digit line 608 may include applying a voltage to the respective line. An access line 606 and/or a digit line 608 may comprise, consist of, or consist essentially of a conductive material, such as a metal (e.g., copper, aluminum, gold, titanium, or tungsten) and/or a metal alloy, among other examples. In FIG. 6, each row of memory cells 604 is connected to a single access line 606, and each column of memory cells 604 is connected to a single digit line 608. By activating one access line 606 and one digit line 608 (e.g., applying a voltage to the access line 606 and digit line 608), a single memory cell 604 may be accessed at (e.g., is accessible via) the intersection of the access line 606 and the digit line 608. The intersection of the access line 606 and the digit line 608 may be called an “address” of a memory cell 604.

In some implementations, the logic storing device of a memory cell 604, such as a capacitor, may be electrically isolated from a corresponding digit line 608 by a selection component, such as a transistor. The access line 606 may be connected to and may control the selection component. For example, the selection component may be a transistor, and the access line 606 may be connected to the gate of the transistor. Activating the access line 606 results in an electrical connection or closed circuit between the capacitor of a memory cell 604 and a corresponding digit line 608. The digit line 608 may then be accessed (e.g., is accessible) to either read from or write to the memory cell 604.

A row decoder 610 and a column decoder 612 may control access to memory cells 604. For example, the row decoder 610 may receive a row address from a memory controller 614 and may activate the appropriate access line 606 based on the received row address. Similarly, the column decoder 612 may receive a column address from the memory controller 614 and may activate the appropriate digit line 608 based on the column address.

Upon accessing a memory cell 604, the memory cell 604 may be read (e.g., sensed) by a sense component 616 to determine the stored data state of the memory cell 604. For example, after accessing the memory cell 604, the capacitor of the memory cell 604 may discharge onto its corresponding digit line 608. Discharging the capacitor may be based on biasing, or applying a voltage, to the capacitor. The discharging may induce a change in the voltage of the digit line 608, which the sense component 616 may compare to a reference voltage (not shown) to determine the stored data state of the memory cell 604. For example, if the digit line 608 has a higher voltage than the reference voltage, then the sense component 616 may determine that the stored data state of the memory cell 604 corresponds to a first value, such as a binary 1. Conversely, if the digit line 608 has a lower voltage than the reference voltage, then the sense component 616 may determine that the stored data state of the memory cell 604 corresponds to a second value, such as a binary 0. The detected data state of the memory cell 604 may then be output (e.g., via the column decoder 612) to an output component 618 (e.g., a data buffer). A memory cell 604 may be written (e.g., set) by activating the appropriate access line 606 and digit line 608. The column decoder 612 may receive data, such as input from input component 620, to be written to one or more memory cells 604. A memory cell 604 may be written by applying a voltage across the capacitor of the memory cell 604.

The memory controller 614 may control the operation (e.g., read, write, re-write, refresh, and/or recovery) of the memory cells 604 via the row decoder 610, the column decoder 612, and/or the sense component 616. The memory controller 614 may generate row address signals and column address signals to activate the desired access line 606 and digit line 608. The memory controller 614 may also generate and control various voltages used during the operation of the memory array 602.

In some implementations, the memory device 600 includes the conductive layer 230 and/or an integrated assembly that includes the conductive layer 230. For example, the memory array 602 may include the conductive layer 230 and/or an integrated assembly that includes the conductive layer 230. Additionally, or alternatively, the memory cell 604 may include a memory cell described elsewhere herein.

As indicated above, FIG. 6 is provided as an example. Other examples may differ from what is described with respect to FIG. 6.

The foregoing disclosure provides illustration and description but is not intended to be exhaustive or to limit the implementations to the precise forms disclosed. Modifications and variations may be made in light of the above disclosure or may be acquired from practice of the implementations described herein.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

In some implementations, an integrated assembly includes a semiconductor device, comprising: a columnar active area, comprising: a semiconductive material; and a tip region having rounded convex corners that transition from a lateral surface of the columnar active area to vertical sidewalls of the columnar active area; and a pad structure directly conjoined with the tip region, comprising: a conductive material; and an inner profile that conforms to the rounded convex corners, the lateral surface, and at least a portion of the vertical sidewalls.

In some implementations, an apparatus includes a source/drain region, comprising: polysilicon; and an end region, comprising: a first lateral surface area; and outwardly filleted edges; a cell contact pad structure, comprising: a doped semiconductive material; and a second lateral surface area, wherein the second lateral surface area is greater than the first lateral surface area; a grain boundary that electrically couples the cell contact pad structure with the source/drain region, comprising: a profile that conforms to the end region having the outwardly filleted edges; and a cell contact structure that electrically couples a capacitor to the source/drain region through the cell contact pad structure and the grain boundary.

In some implementations, a method includes receiving a semiconductor structure including an array of word lines and an array of columnar active areas, wherein a patterned hard mask structure is directly on the array of word lines, and wherein a first patterned dielectric layer that is directly on the array of columnar active areas interleaves with the patterned hard mask structure; removing the first patterned dielectric layer to form a first pattern of approximately linear channels running along sidewalls of the patterned hard mask structure; removing a portion of a second patterned dielectric layer to form a second pattern of approximately linear channels running along sidewalls of the array of columnar active areas, wherein removing the portion of the second patterned dielectric layer removes portions of the columnar active areas to form tips having rounded convex corners; forming a conductive layer over the patterned hard mask structure and over the array of columnar active areas, wherein forming the conductive layer fills the first pattern of approximately linear channels and the second pattern of approximately linear channels; removing a first portion of the conductive layer to define first cross-sections of an array of pad structures on the array of columnar active areas; and removing a second portion of the conductive layer to define second cross-sections of the array of pad structures on the array of columnar active areas.

In some implementations, a method includes receiving a memory structure including a hard mask structure that is patterned over word line structures; forming a pattern of approximately linear channels between segments of the hard mask structure; and forming an array of cell contact pad structures using the pattern of approximately linear channels, wherein forming the array of cell contact pad structures self-aligns the array of cell contact pad structures to an underlying array of source/drain regions using the pattern of approximately linear channels.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
a semiconductor device, comprising:
a columnar active area, comprising:
a semiconductive material; and
a tip region having rounded convex corners that transition from a lateral surface of the columnar active area to vertical sidewalls of the columnar active area; and
a pad structure directly conjoined with the tip region, comprising:
a conductive material; and
an inner profile that conforms to the rounded convex corners, the lateral surface, and at least a portion of the vertical sidewalls.

2. The integrated assembly of claim 1, wherein the conductive material comprises:
a doped polysilicon material.

3. The integrated assembly of claim 1, wherein the conductive material comprises:
a silicide material.

4. The integrated assembly of claim 1, wherein the tip region has an approximately trapezoidal top view profile.

5. An apparatus, comprising:
a source/drain region, comprising:
polysilicon; and
an end region, comprising:
a first lateral surface area; and
outwardly filleted edges;
a cell contact pad structure, comprising:
a doped semiconductive material; and
a second lateral surface area,
wherein the second lateral surface area is greater than the first lateral surface area;
a grain boundary that electrically couples the cell contact pad structure with the source/drain region, comprising:
a profile that conforms to the end region having the outwardly filleted edges; and
a cell contact structure that electrically couples a capacitor to the source/drain region through the cell contact pad structure and the grain boundary.

6. The apparatus of claim 5, wherein the grain boundary conjoins the outwardly filleted edges with the doped semiconductive material.

7. The apparatus of claim 6, wherein the grain boundary comprises:
a junction between crystal structures of the polysilicon and the doped semiconductive material.

8. The apparatus of claim 6, wherein the grain boundary comprises:
discontinuities between crystal structures of the polysilicon and the doped semiconductive material.

9. The apparatus of claim 6, wherein a first cross-sectional shape of the cell contact pad structure along a first plane is a first polygon comprising two segments,
wherein the two segments are approximately orthogonal to one another,
wherein a second cross-sectional shape of the cell contact pad structure along a second plane is a second polygon comprising three segments,
wherein two of the three segments are approximately parallel to each other.

10. A method, comprising:
receiving a semiconductor structure including an array of word lines and an array of columnar active areas,
wherein a patterned hard mask structure is directly on the array of word lines, and
wherein a first patterned dielectric layer that is directly on the array of columnar active areas interleaves with the patterned hard mask structure;
removing the first patterned dielectric layer to form a first pattern of approximately linear channels running along sidewalls of the patterned hard mask structure;
removing a portion of a second patterned dielectric layer to form a second pattern of approximately linear channels running along sidewalls of the array of columnar active areas,
wherein removing the portion of the second patterned dielectric layer removes portions of the columnar active areas to form tips having rounded convex corners;
forming a conductive layer over the patterned hard mask structure and over the array of columnar active areas,
wherein forming the conductive layer fills the first pattern of approximately linear channels and the second pattern of approximately linear channels;
removing a first portion of the conductive layer to define first cross-sections of an array of pad structures on the array of columnar active areas; and
removing a second portion of the conductive layer to define second cross-sections of the array of pad structures on the array of columnar active areas.

11. The method of claim 10, wherein forming the conductive layer includes:
forming the conductive layer using an epitaxial growth operation to grow a semiconductive layer, and
doping the semiconductive layer.

12. The method of claim 10, wherein forming the conductive layer includes:
forming a metallic layer.

13. The method of claim 10, wherein forming the conductive layer includes:
forming the conductive layer using a deposition operation to deposit the conductive layer, and
planarizing the conductive layer after the deposition operation.

14. The method of claim 10, wherein forming the array of columnar active areas includes forming the array of columnar active areas from polysilicon, and
wherein forming the conductive layer includes:
forming the conductive layer by depositing a metal on the polysilicon, and
annealing the metal and the polysilicon to form a silicide.

15. The method of claim 10, wherein removing the first portion of the conductive layer electrically isolates the array of pad structures across segments of the patterned hard mask structure.

16. The method of claim 10, wherein removing the second portion of the conductive layer electrically isolates the array of pad structures across the array of columnar active areas.

17. The method of claim 10, wherein removing the first portion of the conductive layer and removing the second portion of the conductive layer uses the patterned hard mask structure to self-align the array of pad structures to the array of columnar active areas.

18. The method of claim 10, wherein removing the first portion includes:
removing the first portion using an etch back operation.

19. The method of claim 10, wherein removing the second portion includes:
patterning a layer of photoresist over the conductive layer; and
removing the second portion using a subtractive etch operation.

20. The method of claim 10, further comprising:
forming a dielectric layer over the array of pad structures that conforms to surfaces of the array of pad structures, conjoins with the rounded convex corners, and extends below top surfaces of the patterned hard mask structure.
